(19) United States
(12) Patent Application Publication
(10) Pub. No.: US 2020/0021189 A1
(43) Pub. Date: Jan. 16, 2020

(54) CURRENT BALANCE METHOD USED IN MULTI-PHASE SWITCHING CONVERTERS

(71) Applicant: Chengdu Monolithic Power Systems Co., Ltd., Chengdu (CN)

(72) Inventor: Lei Li, Chengdu (CN)

(21) Appl. No.: 16/033,154

(22) Filed: Jul. 11, 2018

(51) Int. Cl. H02M 3/158; H03F 3/45; H02M 1/08; H02M 3/157

(52) U.S. Cl. CPC H02M 3/158; H03F 3/45071; H02M 1/08; H02M 2001/0009; H03F 2200/129; H03F 2200/462; H03F 2200/171; H02M 3/157

(57) ABSTRACT

A current balance method used in multi-phase switching converters, including: generating an error amplifying signal based on a reference voltage signal and a feedback voltage signal indicative of an output voltage of the multi-phase converter; generating a first and second voltage signals respectively indicative of output currents of a first and second switching circuits; generating an average voltage signal indicative of the average value of the first and second voltage signals; generating a first adjusting voltage signal based on the average voltage signal and the first voltage signal; comparing a sum of the error amplifying signal and the first adjusting voltage signal with a first current sensing signal indicative of the current flowing through a transistor in the first switching circuit, to provide a first comparison signal; and generating a first control signal based on the first comparison signal to control the transistor.

### CROSS-REFERENCE TO RELATED APPLICATIONS

This application claims the benefit of CN application 201710753771.1, filed on Aug. 29, 2017, and incorporated herein by reference.

### TECHNICAL FIELD

The present invention generally relates to electronic circuits, and more particularly but not exclusively, to multi-phase switching converters.

### BACKGROUND

Being able to provide high current with low output current ripple, small output capacitance and optimized heat distribution, multi-phase switching converters are widely utilized in medium and large power applications. However, because of deviation in load characteristics and control parameters, currents generated by each of the phases (parallel connected switching circuits in the multi-phase switching converter) are not identical, which causes an adverse impact on the output current ripple and also safe operation of the converter. Therefore, it is crucial to balance the aforementioned phase currents in multi-phase applications.

### SUMMARY

Embodiments of the present invention are directed to a controller used in multi-phase switching converters, wherein the multi-phase converter includes a first switching circuit and a second switching circuit coupled in parallel. The controller comprises: an error amplifying circuit configured to generate an error amplifying signal based on a reference voltage signal and a feedback voltage signal indicative of an output voltage of the multi-phase converter; a first current sensing circuit configured to generate a first voltage signal indicative of an output current of the first switching circuit; a first current averaging circuit having an input terminal and an output terminal, wherein the input terminal is coupled to the first current sensing circuit to receive the first voltage signal; a second current sensing circuit configured to generate a second voltage signal indicative of an output current of the second switching circuit; a second current averaging circuit having an input terminal and an output terminal, wherein the input terminal is coupled to the second current sensing circuit to receive the second voltage signal, the output terminals of the first and second current averaging circuits are coupled together to generate an average voltage signal indicative of an average value of the first and second voltage signals; a first amplifier having a first input terminal, a second input terminal and an output terminal, wherein the first input terminal is configured to receive the average voltage signal, the second input terminal is configured to receive the first voltage signal, and the output terminal is coupled to the error amplifying signal through a first resistor; a first comparing circuit having a first input terminal, a second input terminal and an output terminal, wherein the first input terminal is coupled to the output terminal of the first amplifier, the second input terminal is configured to receive a first current sensing signal indicative of the current flowing through a transistor in the first switching circuit, and the output terminal is configured to provide a first comparison signal; and a first logic circuit configured to generate a first control signal based on the first comparison signal, to control the transistor in the first switching circuit.

Embodiments of the present invention are also directed to a multi-phase switching converter, comprising: an input port configured to receive an input voltage; an output port configured to provide an output voltage; a first switching circuit and a second switching circuit coupled between the input and output ports in parallel; a feedback circuit coupled to the output port and configured to generate a feedback voltage signal indicative of the output voltage; an error amplifying circuit configured to generate an error amplifying signal based on a reference voltage signal and the feedback voltage signal; a first current sensing circuit configured to generate a first voltage signal indicative of an output current of the first switching circuit; a first current averaging circuit having an input terminal and an output terminal, wherein the input terminal is coupled to the first current sensing circuit to receive the first voltage signal; a second current sensing circuit configured to generate a second voltage signal indicative of an output current of the second switching circuit; a second current averaging circuit having an input terminal and an output terminal, wherein the input terminal is coupled to the second current sensing circuit to receive the second voltage signal, the output terminals of the first and second current averaging circuits are coupled together to generate an average voltage signal indicative of the average value of the first and second voltage signals; a first amplifier having a first input terminal, a second input terminal and an output terminal, wherein the first input terminal is configured to receive the average voltage signal, the second input terminal is configured to receive the first voltage signal, and the output terminal is coupled to the error amplifying signal through a first resistor; a first comparing circuit having a first input terminal, a second input terminal and an output terminal, wherein the first input terminal is coupled to the output terminal of the first amplifier, the second input terminal is configured to receive a first current sensing signal indicative of the current flowing through a transistor in the first switching circuit, and the output terminal is configured to provide a first comparison signal; and a first logic circuit configured to generate a first control signal based on the first comparison signal, to control the transistor in the first switching circuit.

Embodiments of the present invention are further directed to a current balance method used in multi-phase switching converters, wherein the multi-phase converter includes a first switching circuit and a second switching circuit coupled in parallel. The method comprises: generating a feedback voltage signal indicative of an output voltage of the multi-phase converter; generating an error amplifying signal based on a reference voltage signal and the feedback voltage signal; generating a first voltage signal indicative of an output current of the first switching circuit; generating a second voltage signal indicative of an output current of the second switching circuit; generating an average voltage signal indicative of the average value of the first and second voltage signals; generating a first adjusting voltage signal based on the average voltage signal and the first voltage signal; comparing a sum of the error amplifying signal and the first adjusting voltage signal with a first current sensing signal indicative of the current flowing through a transistor in the first switching circuit, to provide a first comparison signal; and generating a first control signal based on the first comparison signal, to control the transistor in the first switching circuit.

### BRIEF DESCRIPTION OF THE DRAWING

The present invention can be further understood with reference to the following detailed description and the appended drawings, wherein like elements are provided with like reference numerals.

FIG. 1 is a block diagram of a multi-phase switching converter 100 in accordance with an embodiment of the present invention.

FIG. 2 schematically illustrates a multi-phase switching converter 100A in accordance with an embodiment of the present invention.

FIG. 3 schematically illustrates a multi-phase switching converter 100B in accordance with an embodiment of the present invention.

FIG. 4 schematically illustrates a multi-phase switching converter 100C in accordance with an embodiment of the present invention.

FIG. 5 is a block diagram of a multi-phase switching converter 200 in accordance with an embodiment of the present invention.

FIG. 6 is a flowchart of current balance methods used in multi-phase switching converters in accordance with an embodiment of the present invention.

### DETAILED DESCRIPTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well-known methods, procedures, components, and circuits have not been described in detail so as not to unnecessarily obscure aspects of the present invention.

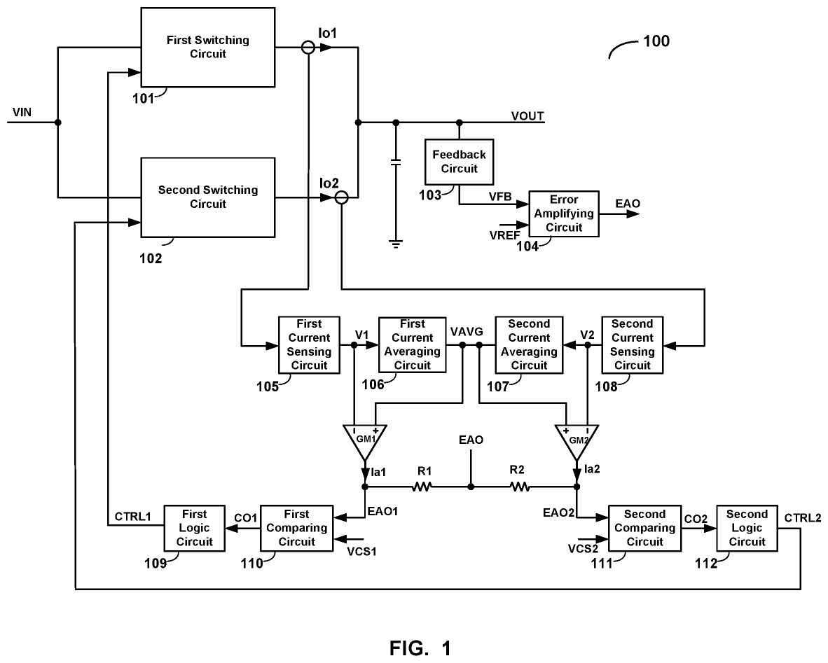

FIG. 1 is a block diagram of a multi-phase switching converter 100 in accordance with an embodiment of the present invention. The switching converter 100 includes an input port configured to receive an input voltage VIN, an output port configured to provide an output voltage VOUT, a first switching circuit 101 and a second switching circuit 102 coupled between the input and output ports in parallel, and a controller used to control the first and second switching circuits. The switching circuits 101 and 102 could be configured in same topology, such as BUCK, BOOST, BUCK-BOOST, FLYBACK, FORWARD and so on, and transistors contained therein are typically controllable semiconductor transistors such as MOSFET.

A feedback circuit 103 is coupled to the output port and configured to generate a feedback voltage signal VFB indicative of the output voltage VOUT. The error amplifying circuit 104 is coupled to the feedback circuit 103, and is configured to generate an error amplifying signal EAO based on the feedback voltage signal VFB and a reference voltage signal VREF. Generally, a normal operational amplifier or a trans-conductance amplifier could be incorporated in the error amplifying circuit 104.

The first current sensing circuit 105 is coupled to the first switching circuit 101, and configured to generate an output current sensing signal which is indicative of an output current Io1 of the first switching circuit and labeled as a voltage signal V1. The first current averaging circuit 106 has an input terminal and an output terminal, wherein the input terminal is coupled to the first current sensing circuit 105 to receive the voltage signal V1. The second current sensing circuit 108 is coupled o the second switching circuit 102, and configured to generate an output current sensing signal which is indicative of an output current Io2 of the second switching circuit and labeled as a voltage signal V2. The second current averaging circuit 107 has an input terminal and an output terminal, wherein the input terminal is coupled to the second current sensing circuit 108 to receive the voltage signal V2, the output terminals is coupled to the output terminal of the first current averaging circuit 106 to generate an average voltage signal VAVG indicative of an average value of the voltage signals V1 and V2. The current sensing circuits 105 and 108 could respectively sense the output currents Io1 and Io2 in a direct or indirect way, for instance, through any of sensing resistors, current amplifiers and current mirrors. The current averaging circuits 106 and 107 might include resistors with pretty large resistance (e.g. tens of kilo ohms), or filters consisting of resistors and capacitors.

The amplifier GM1 has a first input terminal, a second input terminal and an output terminal, wherein the first input terminal is coupled to the output terminals of the current averaging circuits 106 and 107 to receive the average voltage signal VAVG, the second input terminal is coupled to the first current sensing circuit 105 to receive the voltage signal V1, and the output terminal is coupled to the error amplifying signal EAO through a resistor R1. The first comparing circuit 110 has a first input terminal, a second input terminal and an output terminal, wherein the first input terminal is coupled to the output terminal of the amplifier GM1, the second input terminal is configured to receive a first current sensing signal VCS1 indicative of the current flowing through a transistor in the first switching circuit 101, and the output terminal is configured to provide a first comparison signal CO1. The first logic circuit 109 is coupled to the output terminal of the first comparing circuit 110, and configured to generate a first control signal CTRL1 based on the first comparison signal CO1, to control the transistor in the first switching circuit 101

The amplifier GM2 has a first input terminal, a second input terminal and an output terminal, wherein the first input terminal is coupled to the output terminals of the current averaging circuits 106 and 107 to receive the average voltage signal VAVG, the second input terminal is coupled to the second current sensing circuit 108 to receive the voltage signal V2, and the output terminal is coupled to the error amplifying signal EAO through a resistor R2. The second comparing circuit 111 has a first input terminal, a second input terminal and an output terminal, wherein the first input terminal is coupled to the output terminal of the amplifier GM2, the second input terminal is configured to receive a second current sensing signal VCS2 indicative of the current flowing through a transistor in the second switching circuit 102, and the output terminal is configured to provide a second comparison signal CO2. The second logic circuit 112 is coupled to the output terminal of the second comparing circuit 111, and is configured to generate a second control signal CTRL2 based on the second comparison signal CO2, to control the transistor in the second switching circuit 102.

The amplifiers GM1 and GM2 could be trans-conductance amplifiers which convert a differential input voltage into an output current with a constant gain gm. The output current la1 of the amplifier GM1 could be expressed as:

Ia1=(VAVG−V1)*gm

Then the voltage EAO1 at the output terminal of the amplifier GM1 and provided to the first input terminal of the first comparing circuit 110 is:

EAO1=EAO+Ia1*R1=EAO+(VAVG−V1)*gm*R1

Similarly, the voltage EAO2 provided to the first input terminal of the second comparing circuit 111 could be expressed as:

EAO2=EAO+(VAVG−V2)*gm*R2

The embodiment shown in FIG. 1 generates adjusting voltage signals (VAVG−V1)*gm*R1 and (VAVG−V2)*gm*R2 in accordance with the difference between the voltage signals V1, V2 and VAVG, to achieve a fine tuning on the error amplifying signal EAO. By doing so, the control signals CTRL1 and CTRL2 could be altered for equalizing the output currents of the switching circuits 101 and 102.

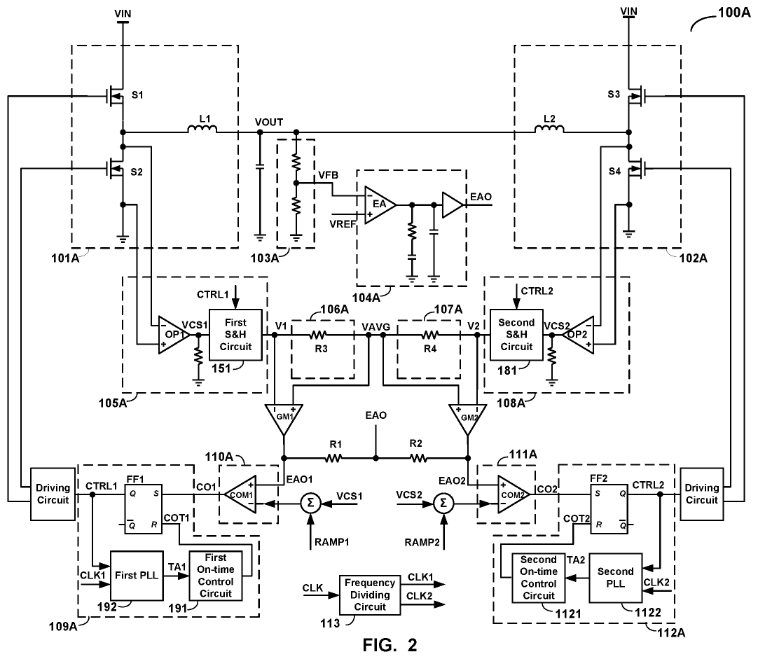

FIG. 2 schematically illustrates a multi-phase switching converter 100A in accordance with an embodiment of the present invention, wherein the switching circuits 101A and 102A are both configured in synchronous BUCK. The switching circuit 101A includes transistors S1, S2 and an inductor L1, while the switching circuit 102A includes transistors S3, S4 and an inductor L2. The feedback circuit 103A is constituted by a resistor divider. The error amplifying circuit 104A includes an error amplifier EA, an impedance network consisting of resistors and capacitors, and a buffer coupled to the output terminal of the error amplifier EA.

The first current sensing circuit 105A comprises an operational amplifier OP1, and a first sample and hold circuit 151. The non-inverting and inverting input terminals of the operational amplifier are respectively couple to drain and source terminals of the transistor S2, and the output terminal is configured to provide a current sensing signal VCS1 indicative of the current flowing through the transistor S2. The first sample and hold circuit 151 is coupled to the output terminal of the operational amplifier OP1, and is configured to sample and hold the current sensing signal VCS1 at the middle point of transistor S2's on-time to generate the voltage signal V1. The first current averaging circuit 106A includes a resistor R3. The first comparing circuit 110A includes a comparator COM1 with its non-inverting input terminal coupled to the output terminal of the amplifier GM1 and inverting input terminal configured to receive a sum of the current sensing signal VCS1 and a ramp compensation signal RAMP1. The first logic circuit 109A comprises a first on-time control circuit 191 and an RS flip-flop FF1. The first on-time control circuit 191 is configured to generate a first on-time control signal COT1 determining the on-time of the transistor S1. The set terminal S of the flip flop FF1 is coupled to the output terminal of the comparator COM1, the reset terminal R is coupled to the first on-time control circuit 191 to receive the first on-time control signal COT1, and the output terminal is configured to provide the control signal CTRL1. Despite of the dead-time influence, the transistor S1 is turned on and the transistor S2 is turned off when the sum of the current sensing signal VCS1 and the ramp compensation signal RAMP1 becomes lower than the signal EAO1. The transistor S1 is turned off and the transistor S2 is turned on when the on-time of the transistor A1 reaches a time threshold set by the first on-time control circuit 191. If the voltage signal V1 is higher than the average voltage signal VAVG, the signal EAO1 will decrease and the off-time of the transistor S1 will be expanded, which causes the frequency as well as the duty cycle of the control signal CTRL1 to decrease and the output current Io1 of the first switching circuit 101A to decline. In this way, the voltage signal V1 will be finally regulated to be equal to the averaging voltage signal VAVG.

Similarly, the second current sensing circuit 108A includes an operational amplifier OP2 and a second sample and hold circuit 181. The second current averaging circuit includes a resistor R4. The second comparing circuit 111A includes a comparator COM2, and the second logic circuit 112A consists of a second on-time control circuit 1121 and an RS flip-flop FF2. The connection and function of these circuits are substantially consistent with what discussed in the previous paragraph and thus are not detailed discussed here for brevity.

In some embodiments, the multi-phase converter further incorporates a frequency dividing circuit 113 to realize interleaving. The frequency dividing circuit generates frequency dividing signals CLK1 and CLK2 in accordance with a clock signal CLK. For dual phase converter, the signals CLK1 and CLK2 has a phase difference in 180 degrees. The first logic circuit 109A further comprises a first PLL (phase lock loop) circuit 192. The first PLL circuit 192 has a first input terminal, a second input terminal and an output terminal, wherein the first input terminal is configured to receive the control signal CTRL1, the second input terminal is configured to receive the frequency dividing signal CLK1, the output terminal is coupled to the first on-time control circuit 191 to generate a time adjusting signal TA1 which is utilized to adjust the first on-time control signal COT1. Through adjusting the time threshold set by the first on-time control circuit 191, the first PLL circuit 192 maintains the control signal CTRL1 and the frequency dividing signal CLK1 substantially in phase. In like manner, the second logic circuit 112A also involves a second PLL circuit 1122 which maintains the control signal CTRL2 and the frequency dividing signal CLK2 substantially in phase through adjusting the time threshold set by the second on-time control circuit 1121.

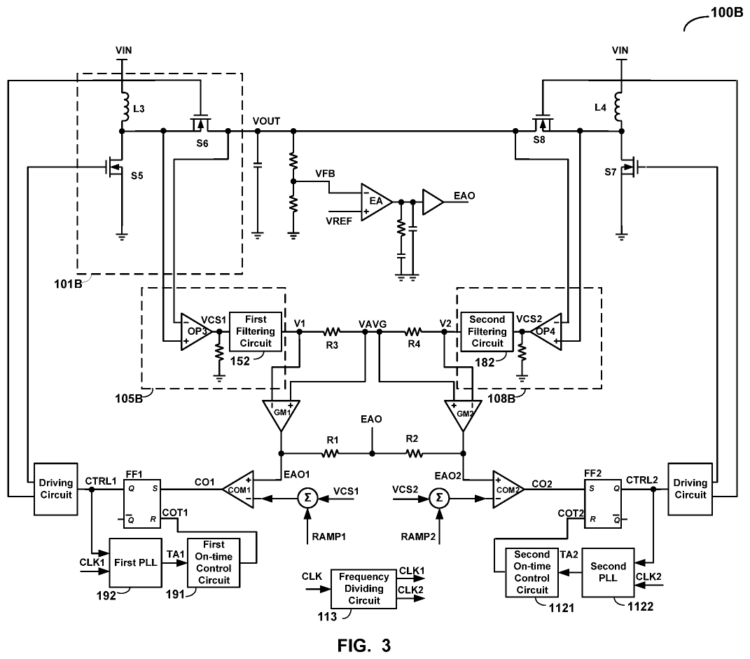

FIG. 3 schematically illustrates a multi-phase switching converter 100B in accordance with an embodiment of the present invention. Compared with the converter 100A shown in FIG. 2, the switching circuits 101B and 102B are configured in a different topology, which is synchronous BOOST. The switching circuit 101B includes transistors S5, S6 and an inductor L3, and the switching circuit 102B includes transistors S7, S8 and an inductor L4. The first current sensing circuit 105B includes an operational amplifier OP3 and a first filtering circuit 152, wherein the non-inverting and inverting input terminals of the operational amplifier OP3 are respectively couple to drain and source terminals of the transistor S6, and the output terminal is configured to provide a current sensing signal VCS1 indicative of the current flowing through the transistor S6. The first filtering circuit 152 filters the current sensing signal VCS1 and provides the filtered signal to the first current averaging circuit as the voltage signal V1. Likewise, the second current sensing circuit 108B includes an operational amplifier OP4 and a second filtering circuit 182, wherein the non-inverting and inverting input terminals of the operational amplifier OP4 are respectively couple to drain and source terminals of the transistor S8, and the output terminal is configured to provide a current sensing signal VCS2 indicative of the current flowing through the transistor S8. The current sensing signal VCS2 is filtered by the second filtering circuit 182 and then provided to the second current averaging circuit as the voltage signal V2. The first and second on-time control circuits 191 and 1121 are respectively configured to determine the on-time of the transistors S5 and S7.

Regarding the first switching circuit 101B, the transistor S5 is turned on and the transistor S6 is turned off when a sum of the current sensing signal VCS1 and the ramp compensation signal RAMP1 becomes lower than the signal EAO1, without consideration of the dead time influence. The transistor S5 is turned off and the transistor S6 is turned on when the on-time of the transistor S5 reaches a time threshold set by the first on-time control circuit 191. Thanks to the amplifier GM1, the voltage signal V1 will be finally regulated to become substantially equal to average voltage signal VAVG.

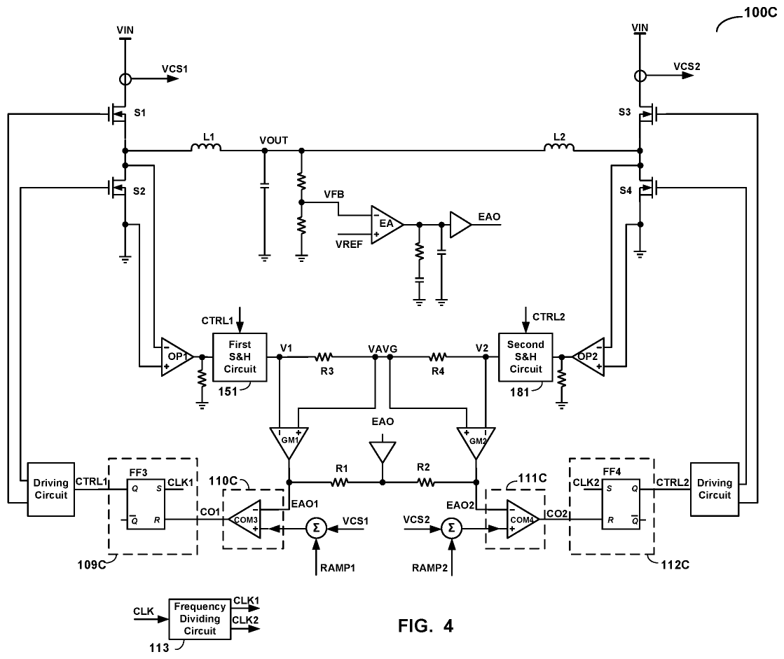

FIG. 4 schematically illustrates a multi-phase switching converter 100C in accordance with an embodiment of the present invention. Compared with the converter 100A of FIG. 2, the first comparing circuit 110C includes a comparator COM3, and the first logic circuit 109C includes an RS flip-flop FF3. The non-inverting input terminal of the comparator COM3 is configured to receive a sum of the current sensing signal VCS1 and the ramp compensation signal RAMP1, wherein the current sensing signal VCS1 represents the current flowing through the transistor S1. The inverting input terminal of the comparator COM3 is coupled to the output terminal of the amplifier GM1 to receive the signal EAO1, and the output terminal is configured to provide the first comparison signal CO1. The set terminal S of the flip flop FF3 is coupled to the frequency dividing circuit 113 to receive the frequency dividing signal CLK1, the reset terminal R is coupled to the output terminal of the comparator COM3, and the output terminal is configured to provide the control signal CTRL1. The transistor S1 is turned on and the transistor S2 is turned off at the rising or falling edge of the frequency dividing signal CLK1. Once the sum of the current sensing signal VCS1 and the ramp compensation signal RAMP1 becomes higher than the signal EAO1, the transistor S1 is turned off and the transistor S2 is turned on.

In the same manner, the second comparing circuit 111C includes a comparator COM4, and the second logic circuit 112C includes an RS flip-flop FF4, connected as shown in the figure. The current sensing signal VCS2 is indicative of the current flowing through the transistor S3.

Although the embodiments described above all adopt dual phase switching converter as examples, people of ordinary skill in the art could recognize that the present invention could also be applied in switching converters with three or more phases. Additionally, the valley current control and fixed frequency peak current control schemes utilized in the embodiments of FIGS. 2-4 are not intended to limit the present invention, and other suitable control methods are also applicable.

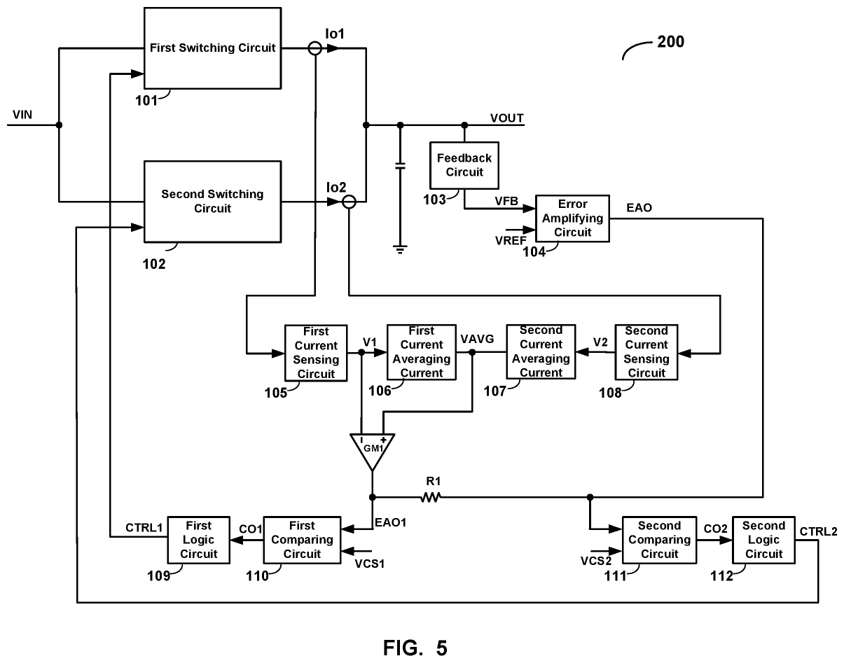

According to embodiments described above, an output current sensing signal of each of the switching circuits is compared with the average voltage signal to adjust the corresponding control signal. Nevertheless, it should be obvious to people of ordinary skills in the art that, it is not necessary to do so in multi-phase switching converters. In an alternative, we can take a certain switching circuit as a master switching circuit and the rest of the switching circuits as slave switching circuits. In this situation, only salve switching circuits need to adopt the current balance scheme provided above to make sure their output current could follow that of the master switching circuit. FIG. 5 is a block diagram of a multi-phase switching converter 200 in accordance with an embodiment of the present invention, wherein the second switching circuit 102 is configured as the master switching circuit and the first switching circuit 101 is configured as the slave switching circuit. Compared with the embodiment of FIG. 1, the amplifier GM2 and resistor R2 are omitted, and the first input terminal of the second comparing circuit 111 is coupled to the error amplifying circuit to receive the error amplifying signal EAO.

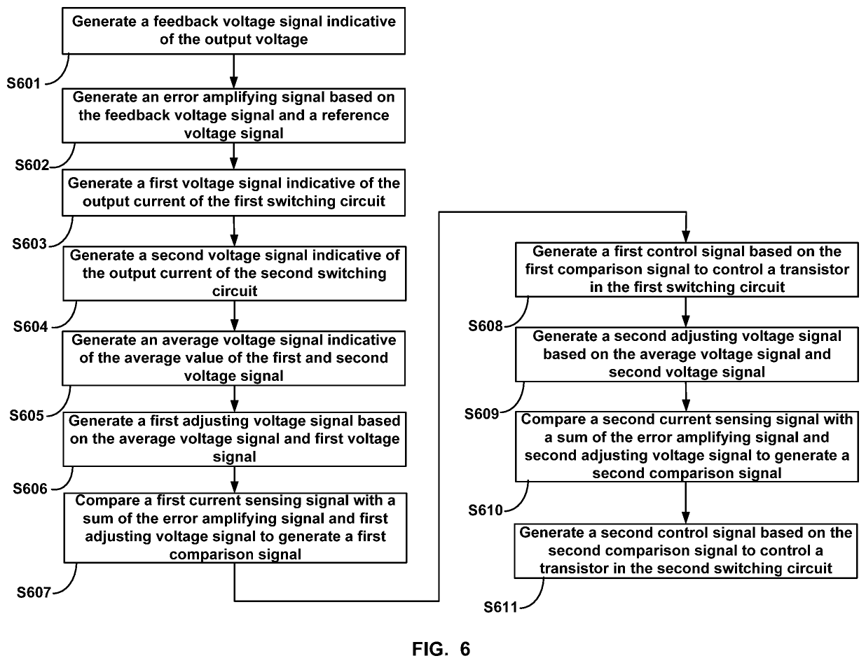

FIG. 6 is a flowchart of current balance methods used in multi-phase switching converters in accordance with an embodiment of the present invention, wherein the multi-phase converter includes a first switching circuit and a second switching circuit coupled in parallel. The current balance method comprises steps S601-S608.

At step S601, a feedback voltage signal indicative of an output voltage of the multi-phase converter is generated.

At step S602, an error amplifying signal is generated based on a reference voltage signal and the feedback voltage signal.

At step S603, a first voltage signal indicative of an output current of the first switching circuit is provided.

At step S604, a second voltage signal indicative of an output current of the second switching circuit is provided.

At step S605, an average voltage signal indicative of an average value of the first and second voltage signals is produced.

At step S606, a first adjusting voltage signal is generated based on the average voltage signal and the first voltage signal.

At step S607, a sum of the error amplifying signal and the first adjusting voltage signal is compared with a first current sensing signal to provide a first comparison signal, wherein the first current sensing signal is indicative of the current flowing through a transistor in the first switching circuit.

At step S608, a first control signal is generated based on the first comparison signal to control the transistor in the first switching circuit.

In some embodiments, the current balance method further includes steps S609-S611. At step S609, a second adjusting voltage signal is generated based on the average voltage signal and the second voltage signal.

At step S610, a sum of the error amplifying signal and the second adjusting voltage signal is compared with a second current sensing signal indicative of the current flowing through a transistor in the second switching circuit, to provide a second comparison signal.

At step S611, a second control signal is generated based on the second comparison signal, to control the transistor in the second switching circuit.

In some embodiments, the first voltage signal is gained through sampling and holding the first current sensing signal, and the second voltage signal is gained through sampling and holding the second current sensing signal. In some other embodiments, the first voltage signal is gained through filtering the first current sensing signal, and the second voltage signal is gained through filtering the second current sensing signal.

Obviously many modifications and variations of the present invention are possible in light of the above teachings. It is therefore to be understood that within the scope of the appended claims the invention may be practiced otherwise than as specifically described. It should be understood, of course, the foregoing disclosure relates only to a preferred embodiment (or embodiments) of the invention and that numerous modifications may be made therein without departing from the spirit and the scope of the invention as set forth in the appended claims. Various modifications are contemplated and they obviously will be resorted to by those skilled in the art without departing from the spirit and the scope of the invention as hereinafter defined by the appended claims as only a preferred embodiment(s) thereof has been disclosed.

1. A controller used in multi-phase switching converters, wherein the multi-phase converter includes a first switching circuit and a second switching circuit coupled in parallel, and the controller comprises:
an error amplifying circuit configured to generate an error amplifying signal based on a reference voltage signal and a feedback voltage signal indicative of an output voltage of the multi-phase converter;
a first current sensing circuit configured to generate a first voltage signal indicative of an output current of the first switching circuit;
a first current averaging circuit having an input terminal and an output terminal, wherein the input terminal is coupled to the first current sensing circuit to receive the first voltage signal, wherein the first current averaging circuit includes a first resistor;
a second current sensing circuit configured to generate a second voltage signal indicative of an output current of the second switching circuit;
a second current averaging circuit having an input terminal and an output terminal, wherein the input terminal is coupled to the second current sensing circuit to receive the second voltage signal, the output terminals of the first and second current averaging circuits are coupled together to generate an average voltage signal indicative of an average value of the first and second voltage signals, wherein the second current averaging circuit includes a second resistor;
a first amplifier having a first input terminal, a second input terminal and an output terminal, wherein the first input terminal is configured to receive the average voltage signal, the second input terminal is configured to receive the first voltage signal, and the output terminal is coupled to the error amplifying signal through a third resistor;
a first comparing circuit having a first input terminal, a second input terminal and an output terminal, wherein the first input terminal is coupled to the output terminal of the first amplifier, the second input terminal is configured to receive a first current sensing signal indicative of the current flowing through a transistor in the first switching circuit, and the output terminal is configured to provide a first comparison signal; and
a first logic circuit configured to generate a first control signal based on the first comparison signal, to control the transistor in the first switching circuit wherein
the error amplifying circuit includes an error amplifier for comparing the reference voltage signal with the feedback voltage signal, an impedance network coupled to an output terminal of the error amplifier, and a buffer coupled between the error amplifying signal and the output terminal of the error amplifier.

2. The controller of claim 1, further comprising:
a second amplifier having a first input terminal, a second input terminal and an output terminal, wherein the first input terminal is configured to receive the average voltage signal, the second input terminal is configured to receive the second voltage signal, and the output terminal is coupled to the error amplifying signal through a fourth resistor;
a second comparing circuit having a first input terminal, a second input terminal and an output terminal, wherein the first input terminal is coupled to the output terminal of the second amplifier, the second input terminal is configured to receive a second current sensing signal indicative of the current flowing through a transistor in the second switching circuit, and the output terminal is configured to provide a second comparison signal; and
a second logic circuit configured to generate a second control signal based on the second comparison signal, to control the transistor in the second switching circuit.

3. The controller of claim 1, wherein the first logic circuit comprises:
a first on-time control circuit configured to generate a first on-time control signal;
a first flip flop having a first input terminal, a second input terminal and an output terminal, wherein the first input terminal is coupled to the output terminal of the first comparing circuit, the second input terminal is coupled to the first on-time control circuit to receive the first on-time control signal, and wherein based on the first comparison signal and the first on-time control signal, the first flip flop generates the first control signal at the output terminal; and
a first phase lock loop circuit having a first input terminal, a second input terminal and an output terminal, wherein the first input terminal is coupled to the output terminal of the first flip flop, the second input terminal is configured to receive a first frequency dividing signal, the output terminal is coupled to the first on-time control circuit, and wherein the first phase lock loop circuit adjusts the first on-time control signal based on the first control signal and the first frequency dividing signal.

4. The controller of claim 1, wherein the first current sensing circuit comprises:
a first operational amplifier having a first input terminal, a second input terminal and an output terminal, wherein the first and second input terminals are respectively couple to drain and source terminals of the transistor in the first switching circuit, and the output terminal is configured to provide the first current sensing signal; and
a first sample and hold circuit having a first input terminal, a second input terminal and an output terminal, wherein the first input terminal is coupled to the output terminal of the first operational amplifier, the second input terminal is coupled to the first logic circuit, and wherein based first control signal, the first sample and hold circuit samples and holds the first current sensing signal and generates the first voltage signal.

5. The controller of claim 1, wherein the first current sensing circuit comprises:
a first operational amplifier having a first input terminal, a second input terminal and an output terminal, wherein the first and second input terminals are respectively couple to drain and source terminals of the transistor in the first switching circuit, and the output terminal is configured to provide the first current sensing signal; and
a first filtering circuit having an input terminal and an output terminal, wherein the input terminal is coupled to the output terminal of the first operational amplifier, and wherein the first filtering circuit filters the first current sensing signal to provide the first voltage signal at the output terminal.

6. A multi-phase switching converter, comprising:
an input port configured to receive an input voltage;
an output port configured to provide an output voltage;
a first switching circuit and a second switching circuit coupled between the input and output ports in parallel;
a feedback circuit coupled to the output port and configured to generate a feedback voltage signal indicative of the output voltage;
an error amplifying circuit configured to generate an error amplifying signal based on a reference voltage signal and the feedback voltage signal;
a first current sensing circuit configured to generate a first voltage signal indicative of an output current of the first switching circuit;
a first current averaging circuit having an input terminal and an output terminal, wherein the input terminal is coupled to the first current sensing circuit to receive the first voltage signal, wherein the first current averaging circuit includes a first resistor;
a second current sensing circuit configured to generate a second voltage signal indicative of an output current of the second switching circuit;
a second current averaging circuit having an input terminal and an output terminal, wherein the input terminal is coupled to the second current sensing circuit to receive the second voltage signal, the output terminals of the first and second current averaging circuits are coupled together to generate an average voltage signal indicative of the average value of the first and second voltage signals, wherein the second current averaging circuit includes a second resistor;
a first amplifier having a first input terminal, a second input terminal and an output terminal, wherein the first input terminal is configured to receive the average voltage signal, the second input terminal is configured to receive the first voltage signal, and the output terminal is coupled to the error amplifying signal through a third resistor;
a first comparing circuit having a first input terminal, a second input terminal and an output terminal, wherein the first input terminal is coupled to the output terminal of the first amplifier, the second input terminal is configured to receive a first current sensing signal indicative of the current flowing through a transistor in the first switching circuit, and the output terminal is configured to provide a first comparison signal; and
a first logic circuit configured to generate a first control signal based on the first comparison signal, to control the transistor in the first switching circuit wherein
the error amplifying circuit includes an error amplifier for comparing the reference voltage signal with the feedback voltage signal, an impedance network coupled to an output terminal of the error amplifier, and a buffer coupled between the error amplifying signal and the output terminal of the error amplifier.

7. The multi-phase switching converter of claim 6, further comprising:
a second amplifier having a first input terminal, a second input terminal and an output terminal, wherein the first input terminal is configured to receive the average voltage signal, the second input terminal is configured to receive the second voltage signal, and the output terminal is coupled to the error amplifying signal through a fourth resistor;
a second comparing circuit having a first input terminal, a second input terminal and an output terminal, wherein the first input terminal is coupled to the output terminal of the second amplifier, the second input terminal is configured to receive a second current sensing signal indicative of the current flowing through a transistor in the second switching circuit, and the output terminal is configured to provide a second comparison signal; and
a second logic circuit configured to generate a second control signal based on the second comparison signal, to control the transistor in the second switching circuit.

8. The multi-phase switching converter of claim 6, wherein the first logic circuit comprises:
a first on-time control circuit configured to generate a first on-time control signal;
a first flip flop having a first input terminal, a second input terminal and an output terminal, wherein the first input terminal is coupled to the output terminal of the first comparing circuit, the second input terminal is coupled to the first on-time control circuit to receive the first on-time control signal, and wherein based on the first comparison signal and the first on-time control signal, the first flip flop generates the first control signal at the output terminal; and
a first phase lock loop circuit having a first input terminal, a second input terminal and an output terminal, wherein the first input terminal is coupled to the output terminal of the first flip flop, the second input terminal is configured to receive a first frequency dividing signal, the output terminal is coupled to the first on-time control circuit, and wherein the first phase lock loop circuit adjusts the first on-time control signal based on the first control signal and the first frequency dividing signal.

9. The multi-phase switching converter of claim 6, wherein the first current sensing circuit comprises:
a first operational amplifier having a first input terminal, a second input terminal and an output terminal, wherein the first and second input terminals are respectively couple to drain and source terminals of the transistor in the first switching circuit, and the output terminal is configured to provide the first current sensing signal; and
a first sample and hold circuit having a first input terminal, a second input terminal and an output terminal, wherein the first input terminal is coupled to the output terminal of the first operational amplifier, the second input terminal is coupled to the first logic circuit, and wherein based on the first control signal, the first sample and hold circuit samples and holds the first current sensing signal and generates a first voltage signal.

10. The multi-phase switching converter of claim 6, wherein the first current sensing circuit comprises:
a first operational amplifier having a first input terminal, a second input terminal and an output terminal, wherein the first and second input terminals are respectively couple to drain and source terminals of the transistor in the first switching circuit, and the output terminal is configured to provide the first current sensing signal; and
a first filtering circuit having an input terminal and an output terminal, wherein the input terminal is coupled to the output terminal of the first operational amplifier, and wherein the first filtering circuit filters the first current sensing signal to provide the first voltage signal at the output terminal.

11-14. (canceled)
